(19) United States
(12) Patent Application Publication
(10) Pub. No.: US 2007/0190685 A1
(43) Pub. Date: Aug. 16, 2007

(54) Cooling facility and method for integrated circuit

(76) Inventor: Ralph Ebbutt, Beaverton, OR (US)

Correspondence Address: THOMAS F. LENIHAN;TEKTRONIX, INC., 14150 S. W. KARL BRAUN DRIVE, P.O. BOX 500 (50-LAW), BEAVERTON, OR, 97077-0001, US

(21) Appl. No.: 11/352,492

(22) Filed: Feb. 10, 2006

(51) Int. Cl. H01L 21/00

(52) U.S. Cl. 438/106

(57) ABSTRACT

An integrated circuit chip has a first part with active circuitry, and a second part with a major surface defining a chamber. The first part covers the second, to enclose the chamber. Inlet and outlet openings are provided in the edge or face of the chip, so that a cooling facility may be connected to each end to transmit coolant through the passage. The chamber may be a serpentine conduit that occupies a plane parallel to the plane of the chip surface or a generally open space enclosed at the periphery, and having spaced apart support elements. The buried passage may be formed by a conventional surface etching process.

### FIELD OF THE INVENTION

The subject invention generally relates to integrated circuits, and more particularly to methods of cooling chips.

### BACKGROUND OF THE INVENTION

Integrated circuit chips generate heat during operation, and this can be a limiting factor for how fast the chips can be operated and how miniaturized they may be made. Efforts to cool high power-density chips such as computer processors generally involve the use of fans or heat pipes to maintain reasonable on-chip temperatures to preserve the reliability and performance of integrated circuit chips.

Other solutions involve positioning cooling devices against chips, with the devices having fluid coolant to carry away heat. Other devices such as disclosed in U.S. Pat. No. 6,673,593 to Mastromatteo, entitled “Integrated device for microfluid thermoregulation, and manufacturing process thereof”, provide buried passages within a semiconductor material body. These passages are used to heat a fluid to a precise temperature for other uses (not for device cooling).

Forming buried passages is difficult and expensive, and does not lend itself well to the conventional lithographic imaging and etching processes used in high-volume semiconductor manufacturing. Moreover, the liquid methods presently employed for cooling integrated circuits generally separate the cooling element from the actual chip, because the packaging of the chip intervenes. This limits the rate of heat flow, and creates a thermal gradient that causes regions of the chip to remain at higher temperatures than the cooling element.

Accordingly, there is a need for a method and apparatus for providing a readily manufacturable facility for cooling an integrated circuit chip.

The preferred embodiment provides this in the following:

### SUMMARY OF THE INVENTION

An integrated circuit chip having a first part with active circuitry, and a second part with a major surface defining a chamber. The first part covers the second, to enclose the chamber. Inlet and outlet openings are provided in the edge or face of the chip, so that a cooling facility may be connected to each end to transmit coolant through the passage. The chamber may be a serpentine conduit that occupies a plane parallel to the plane of the chip surface or a generally open space enclosed at the periphery, and having spaced apart support elements. The buried passage may be formed by a conventional surface etching process.

### BRIEF DESCRIPTION OF THE DRAWINGS

FIG. 1 is an exploded perspective view of a preferred embodiment of the invention.

FIG. 2 is an exploded perspective view of a preferred embodiment of the invention.

FIG. 3 is a schematic view of a preferred embodiment of the invention.

FIG. 4 is a perspective view of a chip according to an alternative embodiment of the invention.

FIG. 5 is a sectional side view of the embodiment of FIG. 4.

### DETAILED DESCRIPTION OF A PREFERRED EMBODIMENT

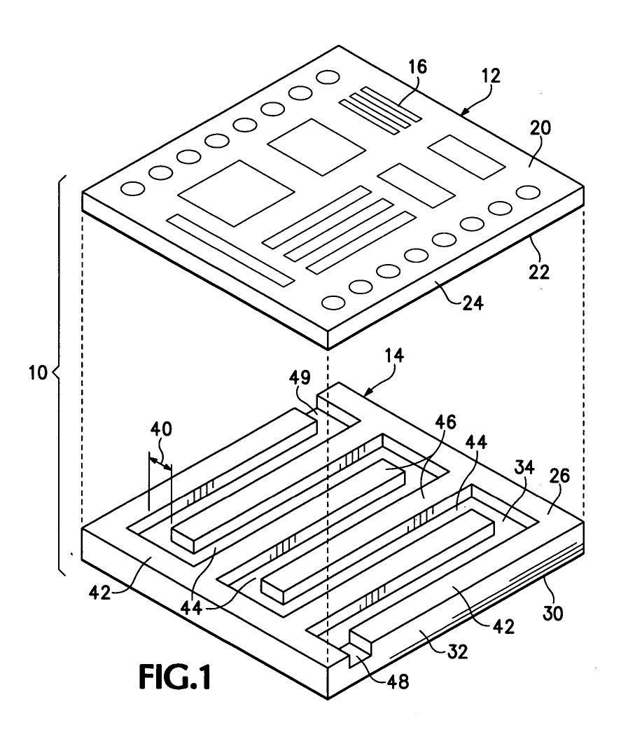

FIG. 1 shows a liquid-cooled integrated circuit assembly 10 with a integrated circuit chip 12 and a channeled substrate 14.

The chip 12 is any conventional semiconductor chip with a pattern 16 of functional circuit elements and conductive traces on an upper surface 20 of the chip, which has a flat lower surface 22. The chip 12 has a rectangular periphery 24.

The substrate is also a flat rectangular element of semiconductor material having an upper surface 26, a lower surface 30, and peripheral edge 32. The substrate's periphery is the same shape and size at that of the chip 12, as will be discussed below. The upper surface defines a serpentine channel 34 that is formed to a consistent partial depth, with a channel floor 36 parallel to and between the upper and lower surfaces 26, 30. The channel has a relatively consistent width 40 that is a minor fraction of the width of the substrate. This narrow channel covers essentially the entire surface of the substrate with a serpentine path that is spaced away from the substrate edges by a margin 42 to provide structural support at the substrate edges.

The intermediate segments 44 of the channels are separated from each other by dividing elements 46 which, like the margins 42, have the full thickness of the substrate, with the upper surface 26 intact. The serpentine path has a total length several times the width of the chip. In the preferred embodiment, for a chip greater than 5 mm wide by greater than 5 mm long, the channel may have a length of 4-5times the width. The only place where the serpentine channel penetrates the periphery is at the ends of the channel, so that an inlet 48 and outlet 49 are defined on opposites edges of the substrate. The substrate channel is formed by a conventional photolithographic process such as etching, or may be formed by any conventional subtractive process that generates an exposed channel without undercuts or blind cuts or buried tunnels being required. This avoids the necessity for more expensive and less precise additive processes.

The buried chamber may be formed by conventional surface etching processes (e.g. chemical etching, partial depth of cut sawing, or ion milling). The resulting cross-section and surface roughness of the channel will vary depending on the surface etching process selected. These standard techniques provide the means to achieve price-performance tradeoffs per the needs of a given application. Intentional creation of micro-surfaces or surface roughness can facilitate more efficient heat transfer to the fluid or gas carrier.

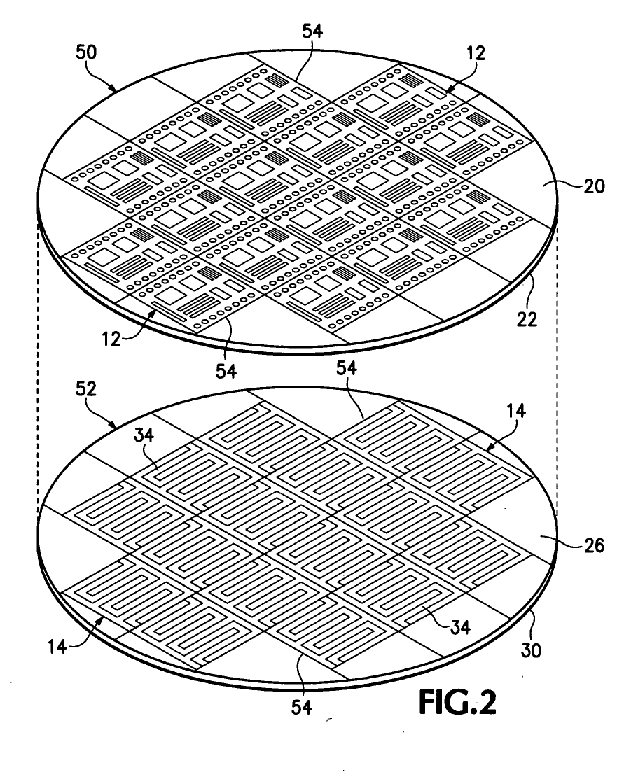

As shown in FIG. 2, the chips 12 are formed in an array on a first wafer 50, and the substrates 14 are formed on a second wafer 52 of the same size. The wafers are formed of the same material, to provide common thermal characteristics thereby minimizing warpage or bending of the overall structure. As shown, each wafer has the same number of sectors each corresponding to a chip, and the borders or cut lines 54 on each wafer are in the same pattern. After the wafers are produced, they are aligned with each other so that the cut lines 54 are aligned, and the lower surface of the upper wafer 50 overlays the upper surface of the lower wafer 52. The two wafers are permanently bonded together by anodic bonding, covalent bonding, solder, glass frit, or adhesive, such that all the non-channel portions of the upper surface 26 of the lower chips are fully sealed by the upper wafer. This ensures that coolant fluid in the channel does not leak beyond the boundaries of the channels or the chips, and does not cross-leak from one leg of the serpentine path to another.

A registration element such as a lithographically defined or laser-ablated fiducial (not shown) on both wafers may be employed to facilitate alignment prior to bonding. Note that the relatively large features of the channels allow the lower wafer to tolerate slight misalignment, by as much as 5-10% of the chip width. Where cooling to the periphery of the chip is less critical, and alignment is more of a challenge, the periphery surrounding the channeled zone may be increased.

After the wafers are bonded, the chips may be singulated by dicing through the wafers along the cut lines 54. Cutting may be based on alignment patterns in the pattern on the exposed upper surface 20 of the upper wafer. This ensures proper alignment with respect to the more alignment-sentisitive active circuitry pattern. Attaching the parts prior to cutting has important manufacturing efficiency advantages over efforts to attach singulated components. That effort generates a process and fixturing challenge, an uncertainty about alignment on each device, and raises the risk of damage by additional handling. In addition, alignment errors may generate a step where one chip overhangs the other, which makes connection to fluid cooling facilities more difficult than a flush cut. This is further exacerbated by the risk of excess bonding agent escaping beyond the chips at the periphery, in the cases where a bonding agent is required (which is not necessary for anodic and covalent wafer bonding).

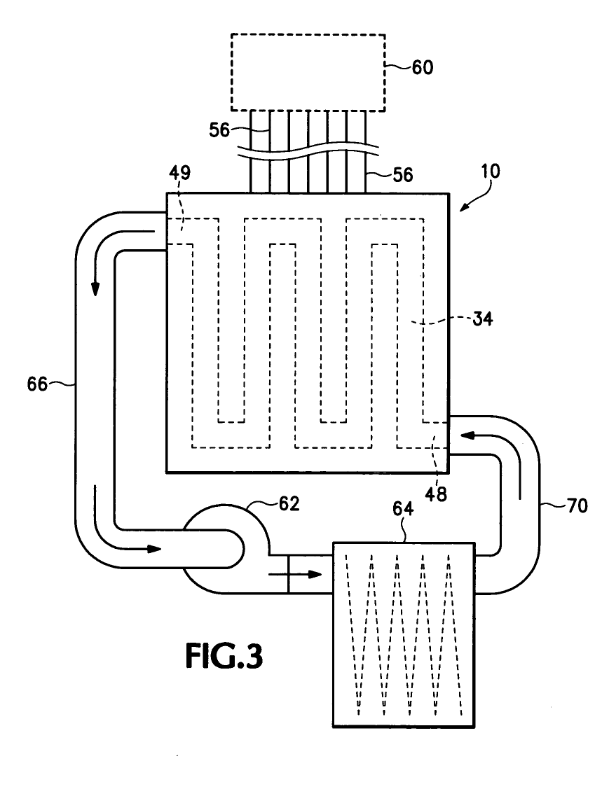

FIG. 3 shows the chip 10 installed in a system for cooling operation. The chip is shown with electrical connections 56 to external circuitry 60, which may include a circuit board or substrate to which the chip is attached. The chip may be connected by any conventional means of electrical bonding to the exposed contacts.

The cooling facility has a pump 62, and a thermal radiator 64 connected serially between the outlet 49 and inlet 48 of the channel 34. The example is shown schematically with conduits 66 and 70 connected to the inlet and outlet. However, in a preferred embodiment, the conduits may not be hose-like elements as shown, but passages in a molded chip carrier or housing. The carrier would have a recess with a periphery that closely receives the chip, with conduit openings adjacent the inlet and outlet, so that a wicking sealant can be applied to provide a seal and allow fluid communication. The carrier may have a larger fluid fitting for connection to cooling elements, such as when a single cooling system is used for multiple chips), or may have an onboard miniature pump and radiator that are electrically, solar, or electro-chemically powered.

The radiator may simply be a reservoir with a thin metal lid exposed to the environment, for radiating the heat at a location away from the chip. A thermo-electric cooler, forced convection fans, and finned radiators may also be employed, together or in combination. The cooling unit may also support other fictions, such as carrying electrical contacts for the chip or providing a reference ground path, so it may serve the dual function of a chip carrier.

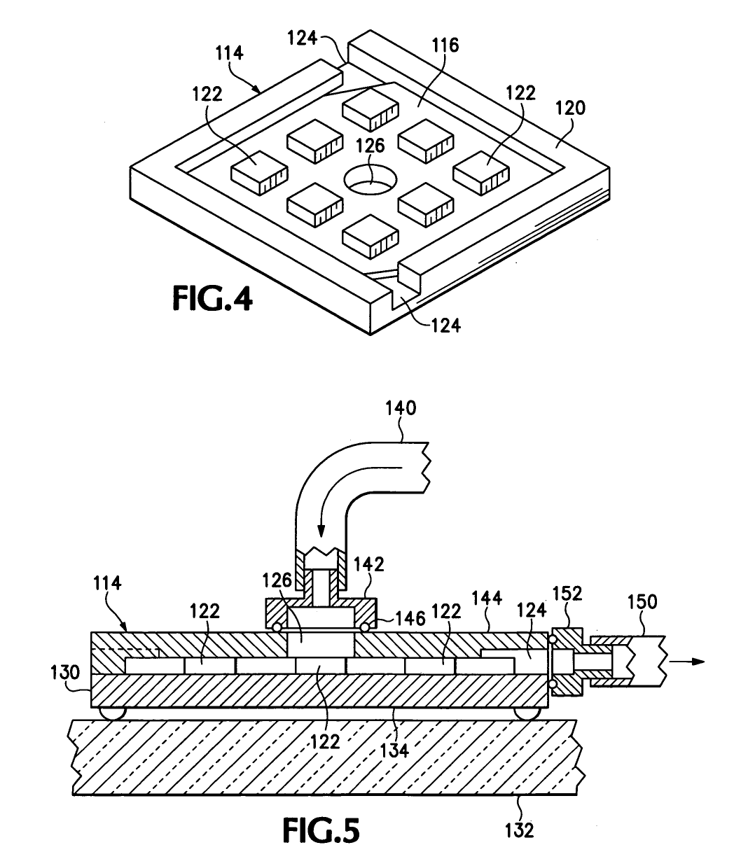

FIG. 4 shows an alternative embodiment chip 114 having a channel pattern or chamber 116 that is essentially an open tray, bounded by a peripheral rim 120. The channel pattern has several islands 122 having upper surfaces in the same plane as the upper surface of the peripheral rim. As in the preferred embodiment, the rim has peripheral apertures 124. In one alternative embodiment, the peripheral apertures may serve as inlet and outlet, respectively. In addition to providing support, the islands 122 may also serve to enhance cooling by providing an increased surface area.

In the illustrated alternative embodiment, both apertures serve as outlets. The chip 114 defines a central aperture 126 that serves as the inlet. In this embodiment, cooling fluid enters the inlet and precedes radially outward toward the outlets. The islands 122 provide barriers to enhance fluid turbulence, so that the corners away from the outlets 124 receive cooling flow. The islands may alternatively be formed as elongated barriers, especially adjacent to the outlets, so that fluid flow is positively diverted to the areas away from the outlets. In the illustrated embodiment, the depth of the channel pattern over most of the chip is a limited depth, less than the depth at areas adjacent to the outlets 124. This avoids constricting the fluid flow at the outlets.

In any embodiment, the cooling fluid may be delivered via a single or multiple through holes, and may be pulsed, as opposed to a continuous flow. In addition, the inlet, outlets, and islands may be positioned to focus the cooling fluid flow at particular hotspots on the chip, so that resources are limited to an adequate level of cooling.

FIG. 5 shows the chip 114 as connected to an integrated circuit 130 that is electrically connected to a circuit board 132. The active, circuitry face 134 of the IC 130 faces the circuit board. A cooling system inlet conduit 140 and inlet fitting 142 are connected to the flat upper surface 144 of the chip 114. The fitting 142 is sealed to the surface with a gasket or adhesive 146. An outlet conduit 150 with an outlet fitting 152 is similarly sealed to the periphery of the assembly at the outlet aperture 124. A similar outlet conduit (not shown) is connected to the other outlet aperture. In operation, cooling fluid flows from the radiator facility, through conduit 140, into the space between the chips, and returns to the radiator via the outlet conduit 150.

In further alternative embodiments, both the inlet and the outlet apertures may be defined in the major surface of the chip, instead of at the periphery. Such apertures would preferably be positioned at opposite diagonal corners of the chip, and would provide the benefit of minimizing the area adjacent to the chip that would be occupied by fluid fittings and conduits, thus freeing space for other components.

The embodiment of FIGS. 4 and 5 may have a chamber in any suitable form, including concentric circles or ellipses, with rings of islands separating the concentric elements. The system may operate by relying on temperature gradients and slight changes in vapor pressure to push or pull heat away from areas of highly acute power density in the integrated circuit chip.

1. An integrated circuit chip comprising:
a first chip element containing active circuitry;
a second chip element having a major surface defining a chamber;
the first chip element overlaying and connected to major surface of the second chip to enclose the chamber; and
the second chip element defining an inlet aperture and an outlet aperture, such that cooling fluid may enter the inlet aperture and exit the outlet aperture to cool the first chip element.

2. The chip of claim 1 wherein the chamber is an elongated channel having a first end, and a second end.

3. The chip of claim 2 wherein at least one of the first and second ends is positioned at a peripheral portion of the second chip element.

4. The chip of claim 2 wherein the channel defines a serpentine path.

5. The chip of claim 1 wherein at least one of the inlet temperature and outlet aperture is defined in the second chip element to penetrate the major surface at a location away from a peripheral edge of the second chip element.

6. The chip of claim 1 wherein the active circuitry resides on a major face of the first chip element facing away from the second chip element.

7. The chip of claim 1 including a cooling facility connected to the chip, the cooling facility having an inlet and an outlet connected to the inlet and outlet apertures.

8. The chip of claim 1 wherein the channel contains a liquid coolant.

9. A method of manufacturing an integrated circuit comprising the steps of:
providing a first wafer having a plurality of first sectors, each first sector including a set of circuitry for an integrated circuit chip;
providing a second wafer having a plurality of second sectors, each second sector corresponding to a first sector of the first wafer;
forming a channel in each second sector, at a major surface of the second wafer;
attaching the first wafer to the major surface of the second wafer; and
singulating the sectors into separate chips.

10. The method of claim 9 wherein forming a channel comprises defining a recess in the major surface of the second wafer.

11. The method of claim 10 wherein defining the recess includes forming the recess to a partial depth of the wafer.

12. The method of claim 9 wherein forming a channel includes etching the second wafer.

13. The method of claim 9 wherein forming a channel includes defining a serpentine channel.

14. The method of claim 9 wherein attaching the first wafer to the second wafer includes sealably enclosing the upper portion of each channel.

15. The method of claim 9 wherein singulating includes exposing an inlet end and an outlet end of the channel at the periphery of each chip.

16. A circuit comprising:
an integrated circuit chip containing active circuitry and having a peripheral edge;
the chip defining a passage within the chip and having an inlet and an outlet at the peripheral edge; and
a cooling facility having conduits connected to the inlet and the outlet, and operable to transmit fluid through the passage.

17. The circuit of claim 16 wherein the passage is a serpentine passage.

18. The circuit of claim 16 wherein the chip is a planar body defining a major plane, and wherein the passage occupies a plane parallel to the major plane.

19. The circuit of claim 16 wherein the chip includes a first portion including circuitry, and a second portion defining the passage in a major face, and wherein the first portion overlays the second portion to enclose the passage.

20. The circuit of claim 16 wherein the cooling facility includes a fluid pump to motivate fluid through the passage.
